(19) United States
(12) Patent Application Publication
(10) Pub. No.: US 2025/0022987 A1
(43) Pub. Date: Jan. 16, 2025

(54) Display Substrate, Manufacturing Method Therefor and Display Device

(71) Applicants: Hefei BOE Ruisheng Technology Co., Ltd., Hefei, Anhui (CN); BOE Technology Group Co., Ltd., Beijing (CN)

(72) Inventors: Jianying ZHANG, Beijing (CN); Jian TIAN, Beijing (CN); Chunjian LIU, Beijing (CN); Yajun MA, Beijing (CN); Jie LEI, Beijing (CN); Nan CHENG, Beijing (CN); Xinhong LU, Beijing (CN)

(21) Appl. No.: 18/280,482

(22) PCT Filed: Oct. 26, 2022
(86) PCT No.: PCT/CN2022/127742

§ 371 Date: Sep. 6, 2023

(51) Int. Cl. H01L 33/46

(52) U.S. Cl. CPC H01L 33/46; H01L 2933/0025

(57) ABSTRACT

A display substrate, a manufacturing method therefor and a display device are provided. The display substrate includes a substrate structure layer, the substrate structure layer includes a substrate material layer, a sacrificial layer and an optical film layer between the substrate material layer and the sacrificial layer which are stacked; a reflectivity of the optical film layer is greater than a transmittance of the optical film layer.

### CROSS-REFERENCE TO RELATED APPLICATION

The present disclosure is a U.S. National Phase Entry of International Application PCT/CN2022/127742 having an international filing date of Oct. 26, 2022, and the contents disclosed in the above-mentioned application are incorporated herein by reference.

### TECHNICAL FIELD

The present disclosure relates to, but is not limited to, the field of display technology, and more particularly, to a display substrate, a method for manufacturing the display substrate, and a display device.

### BACKGROUND

Flexible materials such as PI (polyimide) substrate are widely used in high-end OLED (Organic Light-Emitting Diode) and Mini-LED Display products. In a manufacturing process, the PI substrate needs to be combined with a rigid substrate to be manufactured, and the PI substrate carrying a driving circuit and display chip on a surface of the rigid substrate is processed through a lift off process such as LLO (Laser Lift Off) for subsequent assembly of a whole machine. With increasingly stringent requirements of users on a thickness of the whole machine, the thickness of the whole machine is getting smaller and smaller, which leads to the thickness of the PI substrate to be reduced from the original 100 microns to 50 microns or even below 50 microns.

### SUMMARY

The following is a summary of subject matter described herein in detail. The summary is not intended to limit the protection scope of claims.

An embodiment of the present disclosure provides a display substrate. The display substrate includes a substrate structure layer; the substrate structure layer includes a substrate material layer, a sacrificial layer and an optical film layer between the substrate material layer and the sacrificial layer which are stacked; a reflectivity of the optical film layer is greater than a transmittance of the optical film layer.

In an exemplary embodiment, the optical film layer includes at least one first dielectric layer and at least one second dielectric layer, and a refractive index of the at least one first dielectric layer is less than a refractive index of the at least one second dielectric layer; the at least one first dielectric layer and the at least one second dielectric layer are arranged in an overlapped manner along a direction away from the sacrificial layer.

In an exemplary embodiment, a film layer in the optical film layer adjacent to the substrate material layer is a first dielectric layer, and a film layer in the optical film layer adjacent to the sacrificial layer is a first dielectric layer.

In an exemplary embodiment, a film layer in the optical film layer adjacent to the substrate material layer is a second dielectric layer, and a film layer in the optical film layer adjacent to the sacrificial layer is a second dielectric layer.

In an exemplary embodiment, both the at least one first dielectric layer and the at least one second dielectric layer are made of inorganic materials.

In an exemplary embodiment, a refractive index of a film layer in the optical film layer adjacent to the substrate material layer is greater than a refractive index of the substrate material layer.

In an exemplary embodiment, a refractive index of a film layer in the optical film layer adjacent to the sacrificial layer is greater than a refractive index of the sacrificial layer.

In an exemplary embodiment, a thickness of the sacrificial layer is 2.0 microns to 5.0 microns.

In an exemplary embodiment, a material of the sacrificial layer is a photosensitive organic material or a photosensitive photoresist material.

In an exemplary embodiment, a material of the sacrificial layer is the same as a material of the substrate material layer.

In an exemplary embodiment, the display substrate further includes a circuit structure layer disposed on a side of the substrate material layer away from the sacrificial layer.

In an exemplary embodiment, the display substrate further includes a light emitting element disposed on a side of the circuit structure layer away from the substrate structure layer, wherein the light emitting element is connected to the circuit structure layer.

In an exemplary embodiment, the light emitting element may be a micro light emitting diode or a sub-millimeter light emitting diode.

A display device includes the display substrate described in any of the above embodiments.

A method for manufacturing a display substrate, includes:
forming a sacrificial layer on a carrier substrate;
forming an optical film layer on the sacrificial layer;
forming a substrate material layer on the optical film layer; and
irradiating the sacrificial layer from a side of the carrier substrate away from the sacrificial layer by using lift-off light to lift the sacrificial layer off from the carrier substrate, wherein a reflectivity of the optical film layer is greater than a transmittance of the optical film layer.

Other aspects may be understood upon reading and understanding of the drawings and detailed description.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and do not form limitations on the technical solutions of the present disclosure. Shapes and sizes of components in the drawings do not reflect actual scales, and are only intended to schematically illustrate contents of the present disclosure.

FIG. 1 is a schematic diagram of a display substrate using laser lift-off in related art.

FIG. 2 is a schematic diagram of a structure of a display substrate according to an embodiment of the present disclosure.

FIG. 3A is a schematic diagram of an optical path of lift-off light in a display substrate according to an embodiment of the present disclosure.

FIG. 3B is an enlarged partial view of an optical path of a lift-off light in a display substrate according to an embodiment of the present disclosure.

FIG. 4A is a first schematic diagram of a structure of an optical film layer in a display substrate according to an embodiment of the present disclosure.

FIG. 4B is a second schematic diagram of a structure of an optical film layer in a display substrate according to an embodiment of the present disclosure.

FIG. 5 is a curve graph of laser reflection obtained by simulating an optical film layer in a display substrate according to an embodiment of the present disclosure.

### DETAILED DESCRIPTION

To make objectives, technical solutions, and advantages of the present disclosure clearer, the embodiments of the present disclosure will be described in detail with reference to the accompanying drawings. Implementations may be practiced in a plurality of different forms. Those of ordinary skills in the art may easily understand such a fact that implementations and contents may be transformed into one or more forms without departing from the purpose and scope of the present disclosure. Therefore, the present disclosure should not be explained as being limited to contents described in following implementations only. The embodiments in the present disclosure and features in the embodiments may be combined randomly with each other if there is no conflict.

In the drawings, a size of one or more constituent elements, a thickness of a layer, or a region is sometimes exaggerated for clarity. Therefore, one implementation of the present disclosure is not necessarily limited to the sizes, and shapes and sizes of various components in the drawings do not reflect actual scales. In addition, the drawings schematically illustrate ideal examples, and one implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the description of the present disclosure, “a plurality of” means two or more than two.

In the present disclosure, for convenience, wordings “central”, “up”, “down”, “front”, “back”, “vertical”, “horizontal”, “top”, “bottom”, “inside”, “outside” and the like indicating orientation or positional relationships are used to illustrate positional relationships between constituent elements with reference to the drawings, which are only used to facilitate describing the present specification and simplify the description, rather than indicating or implying that involved devices or elements must have specific orientations and be structured and operated in the specific orientations, and thus should not be understood as limitations on the present disclosure. The positional relationships between the constituent elements are changed as appropriate based on directions for describing the constituent elements. Therefore, appropriate replacements may be made according to situations without being limited to the wordings described in the specification.

In the present disclosure, unless otherwise specified and defined, terms “mounting”, “mutual connection” and “connection” should be understood in a broad sense. For example, a connection may be a fixed connection, a detachable connection, or an integrated connection; it may be a mechanical connection or a connection; it may be a direct connection, an indirect connection through an intermediate component, or an internal communication between two components. Those of ordinary skills in the art may understand meanings of the above-mentioned terms in the present disclosure according to situations.

In the present disclosure, a transistor refers to an element including at least three terminals, namely, a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region and the source electrode. In the present disclosure, the channel region refers to a region through which the mainly current flows.

In the present disclosure, a first electrode may be a drain electrode while a second electrode may be a source electrode, or a first electrode may be a source electrode while a second electrode may be a drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “connection” includes a case where constituent elements are connected through an element with a certain electrical action. The “element with the certain electrical effect” is not particularly limited as long as electrical signals may be sent and received between the connected constituent elements. Examples of the “element with the certain electrical effect” not only include electrodes and wirings, but also include switching elements such as transistors, resistors, inductors, capacitors, other elements with one or more functions, etc.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is defined not so strictly and numerical values within process and measurement error ranges are allowed.

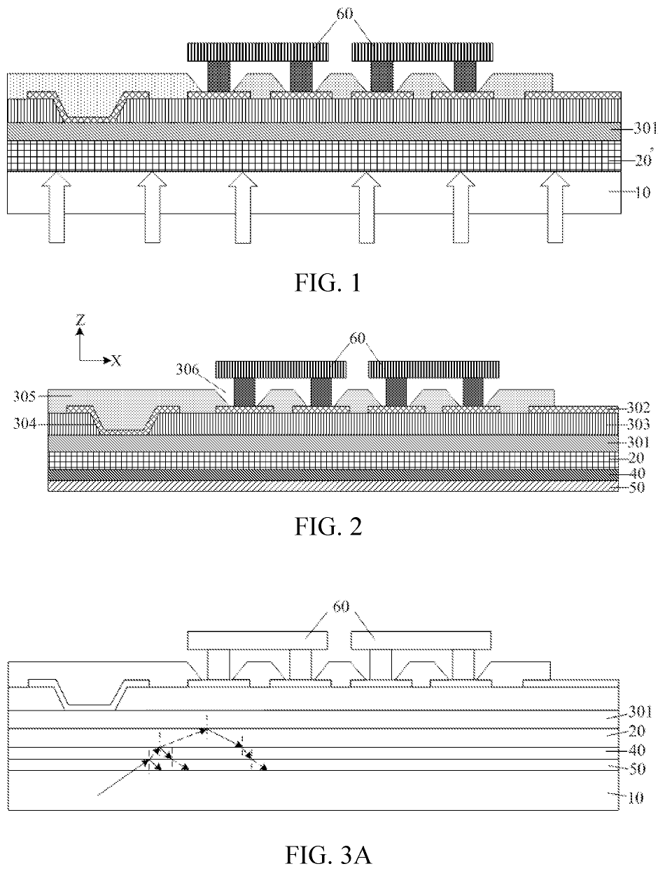

FIG. 1 is a schematic diagram of a display substrate using a laser lift-off in related art; A display substrate in the related art includes a carrier substrate 10, a flexible substrate 20′ disposed on the carrier substrate 10 and a circuit structure layer 301 disposed on the flexible substrate 20′. In a process of lifting off the display substrate by laser in the related art, the laser is incident from a side of the carrier substrate 10 away from the flexible substrate 20′ into the flexible substrate 20′ through the carrier substrate 10, as shown by arrow lines in FIG. 1, the laser enables the flexible substrate 20′ and the carrier substrate 10 to be separated from each other off.

According to the inventor's research, during a lift-off process of the flexible substrate 20′ and the carrier substrate 10, the laser will vaporize part of the flexible substrate 20′ in the structure of the display substrate in the related art to form apertures, or reduce an overall thickness of the flexible substrate 20′, so that most of the laser penetrates through the flexible substrate 20′ and irradiates the circuit structure layer 301 on the flexible substrate 20′, thus the circuit in the circuit structure layer 301 is damaged. The circuit structure layer 301 is usually used to be connected with functional components, such as light emitting elements or driving chips, etc. Damages to circuits in the circuit structure layer 301 will reduce an overall display effect of the display product.

If the energy of laser irradiation is reduced in the lift-off process, there are problems such as difficulty in separating the flexible substrate 20′ from the carrier substrate 10, low lift-off efficiency. During the lift-off process, as the thickness of the flexible substrate 20′ decreases, when small molecular foreign matter is precipitated on a surface of the carrier substrate 10, it is easy to produce bubbling on the flexible substrate 20′, which will reduce airtightness of the display substrate, lead to the failure of the display substrate to pass a reliability evaluation test and increase a defective rate of products.

The present disclosure provides a display substrate including a substrate structure layer. The substrate structure layer includes a substrate material layer, a sacrificial layer and an optical film layer between the substrate material layer and the sacrificial layer which are stacked. A reflectivity of the optical film layer is greater than a transmittance of the optical film layer.

A laser lift-off process may be used for the display substrate of the present disclosure, and the substrate structure layer may be lifted off from the carrier substrate by laser. In this display substrate, the optical film layer is configured to have a reflectivity greater than a transmittance thereof, so that a proportion of lift-off light penetrating through the substrate material layer can be reduced, the damage caused by the lift-off light to the circuit structure layer and the like in the display substrate can be avoided, and a qualified rate of the product can be improved, and an overall manufacturing cost of the display product can be reduced.

The technical solutions of the embodiments of the present disclosure will be illustrated in detail below by the embodiments.

FIG. 2 is a schematic diagram of a structure of a display substrate according to an embodiment of the present disclosure. As shown in FIG. 2, two directions are defined for description of the technical scheme, and a first direction is identified as X and a second direction is identified as Z. The first direction intersects with the second direction. In the embodiment of the present disclosure, the first direction and the second direction are perpendicular to each other. The second direction (Z) is a thickness direction of the display substrate.

In an exemplary implementation, as shown in FIG. 2, the display substrate according to an embodiment of the present disclosure includes a substrate structure layer. The substrate structure layer includes a substrate material layer 20, a sacrificial layer 50, and an optical film layer 40 located between the substrate material layer 20 and the sacrificial layer 50 which are stacked. The optical film layer 40 is configured such that the optical film layer 40 has a reflectivity greater than a transmittance of the optical film layer 40, for example, the reflectivity of the optical film layer 40 may be 60% to 90%, and the transmittance of the optical film layer 40 may be 10% to 40%. For example, the reflectivity of the optical film layer 40 may be 70% to 80%, and the transmittance of the optical film layer 40 may be 20% to 30%. The optical film layer 40 can reduce a proportion of lift-off light incident into the substrate material layer 20 and can prevent the lift-off light from damaging the circuit structure layer 301 and the like in the display substrate. The lift-off light may be laser or the like. The reflectivity of the optical film layer 40 and the transmittance of the optical film layer 40 may be selected according to needs of the display panel as long as the reflectivity of the optical film layer 40 is greater than the transmittance of the optical film layer 40.

In an embodiment of the present disclosure, the technical solution is described by an example in which the lift-off light is provided as laser.

In an exemplary implementation, a side of the sacrificial layer 50 away from the optical film layer 40 is a laser lift-off surface. The laser lift-off surface is a surface of the display substrate after being lift off from the carrier substrate 10 by laser irradiation. The laser lift-off surface can be left with lift-off holes, or uneven surface, or basically flat surface, and the like after the laser irradiation. Different laser lift-off surfaces can be obtained according to different laser settings. For example, the laser may be arranged in points, lines, or surfaces, i.e. constituting a point light source or a line light source or a surface light source. In a process of laser lift-off of the display substrate, laser energy may be absorbed by the sacrificial layer 50 provided, so that a portion of the sacrificial layer 50 is decomposed to form a laser lift-off surface to achieve lift-off of the display substrate from the carrier substrate 10.

In an exemplary implementation, the sacrificial layer 50 may be made of a photosensitive organic material, such as a photosensitive resin material, or the like. Or, the sacrificial layer 50 may be made of a photosensitive photoresist material, or the like. The sacrificial layer 50 may be prepared by an inkjet-printed process.

In an exemplary embodiment, the sacrificial layer 50 may include one of polyimide (PI), polyacrylate, polyphenylene sulfide, polyaryl ester, cellulose acetate propionate, polyethylene naphthalate (PEN), polyethylene terephthalate (PET), polyethersulfone resin (PES), polycarbonate (PC), polyetherimide (PEI), cycloolefin polymer (COP), silica gel resin, polyaryl compound (PAR) or glass fiber reinforced plastic (FRP), or a mixture of a plurality of polymers. When a laser irradiates a polymer, such as a polyimide, the polyimide is carbonized and decomposed due to absorption of light to achieve lift-off of the display substrate from the carrier substrate 10.

In an exemplary implementation, the thickness of the sacrificial layer 50 may be in a range from 2.0 microns (μm) to 5.0 microns (μm).

In an exemplary implementation, a range of a refractive index of the sacrificial layer 50 may be set to be 1.65 to 1.80.

In an exemplary implementation, the reflectivity of the optical film layer 40 is greater than the transmittance thereof. The display substrate can reflect the lift-off light to the sacrificial layer 50 by using a semi-transparent and semi-reflective property of the optical film layer 40, which can generally improve a utilization efficiency of the lift-off light.

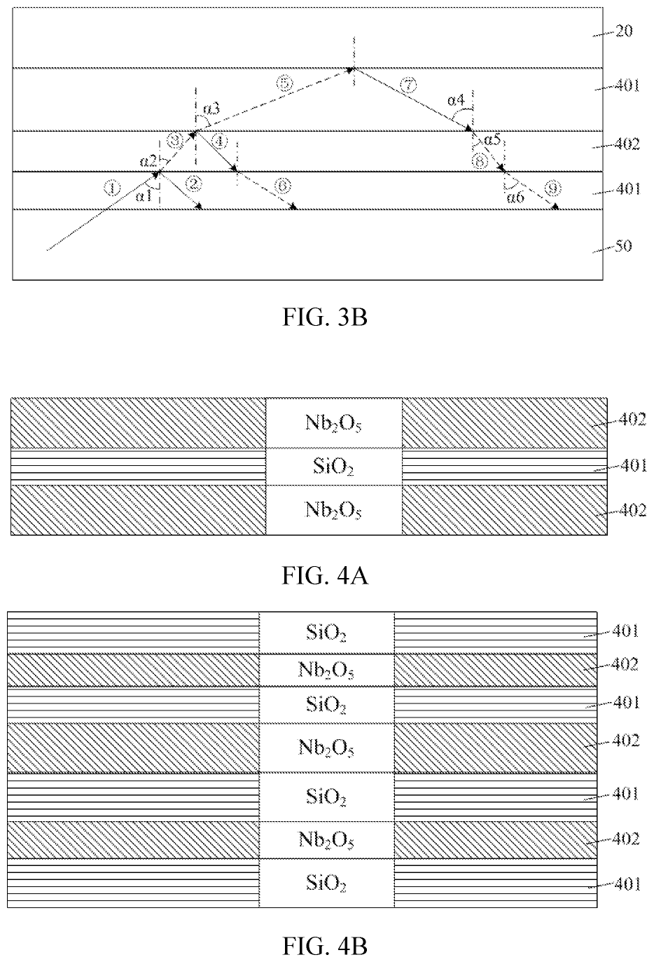

FIG. 3A is a schematic diagram of an optical path of lift-off light in a display substrate according to an embodiment of the present disclosure. The optical film layer 40 may have a multi-film structure and the structure of the optical film layer 40 is simplified in FIG. 3A and is illustrated as a single-layer film layer. FIG. 3B is an enlarged partial view of an optical path of lift-off light in a display substrate according to an embodiment of the present disclosure. For a clear illustration, in FIGS. 3A and 3B, the display substrate is not filled with color, but is illustrated as white frames.

In an exemplary implementation, as shown in FIG. 3A, taking one laser beam as an example, the laser beam enters the sacrificial layer 50 from a side of the carrier substrate 10 away from the sacrificial layer 50, and part of the laser beam passes through the optical film layer 40 and the substrate material layer 20 and then is reflected back to the sacrificial layer 50.

In an exemplary implementation, as shown in FIG. 3B, the optical film layer 40 includes at least one first dielectric layer 401 and at least one second dielectric layer 402, and a refractive index of the first dielectric layer 401 is different from a refractive index of the second dielectric layer 402. In an embodiment of the present disclosure, the refractive index of the first dielectric layer 401 is defined to be less than the refractive index of the second dielectric layer 402. The first dielectric layer 401 and the second dielectric layer 402 within the optical film layer 40 may be arranged in an overlapped manner along a direction away from the sacrificial layer 50. For example, along the direction away from the sacrificial layer 50, the first dielectric layer 401 the second dielectric layer 402 and the first dielectric layer 401 are sequentially arranged in an overlapped manner, as shown in FIG. 3B. Or, along the direction away from the sacrificial layer 50, the second dielectric layer, the first dielectric layer, the second dielectric layer, the first dielectric layer are sequentially arranged in an overlapped manner.

As shown in FIG. 3B, by taking the optical film layer 40 including three film layers as an example, the first dielectric layer 401, the second dielectric layer 402 and the first dielectric layer 401 are arranged in sequence along the direction away from the sacrificial layer 50. By utilizing differences between refractive indices of film layers in the optical film layer 40, a technical effect of semi-transparence and semi-reflection can be realized, and the utilization efficiency of lift-off light can be improved.

According to the optical principle, when light is incident from a material with one refractive index to a material with another refractive index, a transmission route of light will change, and refraction, reflection or total reflection will occur at an interface between the two materials. For example, when light is incident from a material with large refractive index to a material with small refractive index, as an incident angle of the incident light exceeds a critical angle, the incident light will be totally reflected at the interface, and when the incident angle of the incident light does not exceed the critical angle, the incident light will be refracted. By utilizing the differences between refractive indices of the dielectric layers in the optical film layer 40, the proportion of laser incident on the substrate material layer 20 can be reduced, a proportion of light changing the transmission route can be increased, and a proportion of laser reflected back to the sacrificial layer 50 can be increased, which includes reflected light, refracted and then reflected light, or refracted, reflected and then refracted light.

As shown in FIG. 3B, reflection of light is indicated by a solid arrow line, and refraction of light is indicated by a dashed arrow line. The refractive index of the first dielectric layer 401 is set to n1, and the refractive index of the second dielectric layer 402 is set to n2, and n2 is greater than n1. A refractive index of a medium through which the incident light passes is N1, a refractive index of a medium through which the refracted light passes is N2, an incident angle is θ1, a refractive angle is θ2, and the refractive law N1 sin θ 1=N2 sin θ 2 is satisfied. In a process of light transmission, N1, N2, θ 1 and θ 2 are all changed each time the light passes through an interface between two materials with different refractive indices.

As shown in FIG. 3B, taking a laser beam as an example. When light \textcircled{1} passes through an interface between the first dielectric layer 401 and the second dielectric layer 402, a part of the light is reflected to form light \textcircled{2} which can etch the sacrificial layer 50 one more time. The other part of the light \textcircled{1} is refracted to form light \textcircled{3}. When refraction occurs, refraction law is satisfied, that is, n1 sin α 1=n2 sin α 2. When the light \textcircled{3} pass through an interface between the second dielectric layer 402 and the first dielectric layer 401, a part of the light is reflected to form a light \textcircled{4}, and when the light \textcircled{4} pass through the interface between the second dielectric layer 402 and the first dielectric layer 401, the light is refracted to form light (6) which can etch the sacrificial layer 50 one more time. The other part of the light \textcircled{3} is refracted to form light \textcircled{5}. When refraction occurs, refraction law is satisfied, that is, n2 sin α 2=n1 sin α 3. When the light (5) passes through an interface between the first dielectric layer 401 and the base material layer 20, a part of the light is reflected to form a light \textcircled{7}. When the light \textcircled{7} pass through an interface between the first dielectric layer 401 and the second dielectric layer 402, a part of the light will be refracted to form a light \textcircled{8}. When refraction occurs, the refraction law is satisfied, that is, n1 sin α4=n2 sin α5. When the light \textcircled{8} passes through an interface between the second dielectric layer 402 and the first dielectric layer 401, a part of the light is refracted to form a light \textcircled{9}. When refraction occurs, the refraction law is satisfied, that is, n2 sin α5=n1 sin α6, and the light \textcircled{9} can etch the sacrificial layer 50 one more time. The principle of a plurality of lights is the same, so it will not be repeated here.

In some embodiments, the optical film layer 40 may include a plurality of first dielectric layers 401 and a plurality of second dielectric layers 402. The plurality of first dielectric layers 401 and the plurality of second dielectric layers 402 are arranged in an overlapped manner along the direction away from the sacrificial layer 50, a film layer in the optical film layer 40 adjacent to the substrate material layer 20 is a second dielectric layer 402, and a film layer in the optical film layer 40 adjacent to the sacrificial layer 50 is a second dielectric layer 402.

In an exemplary embodiment, the optical film layer 40 may include a plurality of first dielectric layers 401 and a plurality of second dielectric layers 402. The plurality of first dielectric layers 401 and the plurality of second dielectric layers 402 are arranged in an overlapped manner along a direction away from the sacrificial layer 50, a film layer in the optical film layer 40 adjacent to the substrate material layer 20 is a first dielectric layer 401, and a film layer in the optical film layer 40 adjacent to the sacrificial layer 50 is a first dielectric layer 401.

FIG. 4A is a first schematic diagram of a structure of an optical film layer in a display substrate according to an embodiment of the present disclosure. In an exemplary embodiment, as shown in FIG. 4A, the optical film layer 40 may include three sub-layers, which are a second dielectric layer 402 (taking an Nb₂O₅ layer as an example), a first dielectric layer 401 (taking a SiO₂ layer as an example), and a second dielectric layer 402 (taking an Nb₂O₅ layer as an example) arranged in sequence. Along a direction away from the sacrificial layer 50, the second dielectric layer 402, the first dielectric layer 401 and the second dielectric layer 402 are sequentially arranged in an overlapped manner. A refractive index of the first dielectric layer 401 is smaller than a refractive index of the second dielectric layers 402.

In an exemplary embodiment, a film layer in the optical film layer 40 adjacent to the substrate material layer 20 is the first dielectric layer 401, and a film layer in the optical film layer 40 adjacent to the sacrificial layer 50 is the first dielectric layer 401.

FIG. 4B is a second schematic diagram of a structure of an optical film layer in a display substrate according to an embodiment of the present disclosure. In an exemplary embodiment, as shown in FIG. 4B, the optical film layer 40 may include seven sub-layers, which are a first dielectric layer 401 (taking a SiO₂ layer as an example), a second dielectric layer 402 (taking a Nb₂O₅ layer as an example), a first dielectric layer 401, a second dielectric layer 402, a first dielectric layer 401, a second dielectric layer 402, and a first dielectric layer 401 arranged in sequence. Along the direction away from the sacrificial layer 50, the first dielectric layer 401, the second dielectric layer 402, the first dielectric layer 401, the second dielectric layer 402, the first dielectric layer 401, the second dielectric layer 402, and the first dielectric layer 401 are sequentially arranged in an overlapped manner. A refractive index of the first dielectric layers 401 is smaller than a refractive index of the second dielectric layers 402.

In some embodiments, the optical film layer may further include other numbers of first dielectric layers and second dielectric layers that are sequentially arranged in an overlapped manner along the direction away from the sacrificial layer as long as the refractive index of the first dielectric layers is different from the refractive index of the second dielectric layers. Embodiments of the present disclosure are not repeated here.

In the display substrate according to the embodiment of the present disclosure, the optical film layer 40 is provided as a multi-layer structure, and the optical film layer 40 can reflect lasers with different wavelengths by alternately arranging films with different refractive indices, for example, the alternate arrangement of the first dielectric layers 401 and the second dielectric layers 402, so as to improve a diversity of display products. For example, in actual production, it is possible to improve the efficiency of laser lift-off of the display substrate by changing a material combination of a plurality of film layers in the optical film layer 40 without adjusting the existing production equipment.

Table 1 illustrates a structure of an optical film layer to be simulated. The carrier substrate can be glass. Along a direction away from the carrier substrate 10, the optical film layer to be simulated includes a second dielectric layer (Nb₂O₅), a first dielectric layer (SiO₂), and a second dielectric layer (Nb₂O₅) sequentially arranged along the direction away from the carrier substrate. A thickness in Table 1 indicates a thickness of a corresponding film layer, and the thickness being “0” means that the defined thickness of the layer in the simulation software is 0, that is, there is no such film layer in the actual optical film layer.

TABLE 1

| | | Refractive | Optical thickness | Thickness | Thickness |
|---|---|---|---|---|---|
| Layer | Materials | index | (FWOT) | (nm) | (mm) |
| 1 | Nb₂O₅ | 2.38 | 0 | 0 | |
| 2 | SiO₂ | 1.47 | 0 | 0 | |
| 3 | Nb₂O₅ | 2.38 | 0.16 | 35.0 | |
| 4 | SiO₂ | 1.47 | 0.23 | 79.0 | |
| 5 | Nb₂O₅ | 2.38 | 0.27 | 58.0 | |
| 6 | Glass | 1.54 | | | 1.1 |

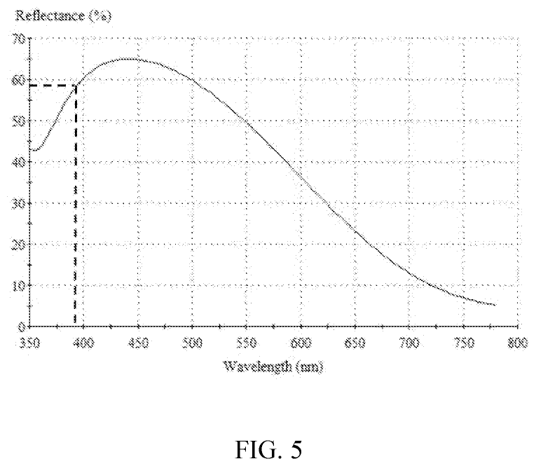

FIG. 5 is a curve graph of laser reflection obtained by simulating an optical film layer in a display substrate according to an embodiment of the present disclosure. A laser reflection simulation experiment is carried out on the optical film shown in Table 1 above, and the simulation experiment results are shown in FIG. 5. Abscissa in FIG. 5 is a laser wavelength in the simulation experiment, and ordinate in FIG. 5 is a reflectance of the optical film to laser in the simulation experiment.

It can be seen from the above experimental results that different reflectivity can be obtained based on the same optical film 40 due to different laser wavelengths. For example, when the wavelength of laser is 400 nm and the reflectivity of the optical film to laser can reach 60%. In actual production, the number of dielectric layers and the materials of the dielectric layer inside the optical film 40 can be adjusted according to the laser wavelengths and the reflectivity required by the design.

In the actual production of the display substrate, different lasers can be selected to obtain the required laser wavelengths. A range of the laser wavelength is from 375 nm to 1650 nm. For example, a range of a laser wavelength of a blue-violet laser is 375 nm, 405 nm. Laser wavelengths of the blue laser are 450 nm, 457 nm and 473 nm. A wavelength of a green laser is 532 nm. A wavelength of a yellow laser is 589 nm. Wavelengths of red laser are 635 nm, 660 nm and so on.

Excimer laser can also be selected. The excimer laser is the laser produced when the molecules formed by a mixed gas of inert gas and halogen gas are excited by electron beam and transitioned to their ground state. The excimer laser belongs to ultraviolet light, and its wavelength ranges from 157 nm to 353 nm. The wavelengths of common excimer lasers are 157 nm, 193 nm, 248 nm and 308 nm.

In an exemplary implementation, both the first dielectric layer 401 and the second dielectric layer 402 may be made of an inorganic material. As an example, the material of the first dielectric layer 401 may include any one of silicon oxynitride (SiOₓN_{y}), silicon nitride (SiN), silicon oxide (SiO), silicon dioxide (SiO₂), aluminum oxide (Al₂O₃), titanium dioxide (TiO₂), niobium pentoxide (Nb₂O₅), etc. The material of the second dielectric layer 402 may include any one of silicon oxynitride (SiOₓN_{y}), silicon nitride (SiN), silicon oxide (SiO), silicon dioxide (SiO₂), aluminum oxide (Al₂O₃), titanium dioxide (TiO₂), niobium pentoxide (Nb₂O₅), etc. It will be acceptable as long as the refractive index of the second dielectric layer 402 is greater than the refractive index of the first dielectric layer 401.

In an exemplary embodiment, the range of the refractive index of the first dielectric layer 401 may be set to 1.4 to 1.6, and the range of the refractive index of the second dielectric layer 402 may be set to 2.0 to 2.3. The two kinds dielectric layers with two refractive indices can be used in combination to realize semi-transparent and semi-reflective optical property, so as to improve the reflectivity of lift-off light and improve the utilization efficiency of light.

In an exemplary embodiment, other film layers may be disposed between the first dielectric layer 401 and the second dielectric layer 402 in the optical film layer 40 which are adjacent. For example, a third dielectric layer may be disposed between the first dielectric layer 401 and the second dielectric layer 402 in the optical film layer 40 which are adjacent. A refractive index of the third dielectric layer is greater than that of the first dielectric layer and smaller than that of the second dielectric layer. The material of the third dielectric layer may include any one of silicon oxynitride (SiOₓN_{y}), silicon nitride (SiN), silicon oxide (SiO), silicon dioxide (SiO₂), aluminum oxide (Al₂O₃), titanium dioxide (TiO₂), niobium pentoxide (Nb₂O₅), etc.

In some embodiments, a fourth dielectric layer or a fifth dielectric layer or the like may be disposed between the first dielectric layer 401 and the second dielectric layer 402 which are adjacent. The refractive indices of the first dielectric layer, the second dielectric layer, the third dielectric layer, the fourth dielectric layer and the fifth dielectric layer are all different, and the arrangement of the plurality of dielectric layers is not limited herein.

In an exemplary embodiment, a refractive index of a film layer in the optical film layer 40 adjacent to the substrate material layer 20 is greater than a refractive index of the substrate material layer 20, which may increase a proportion of light returning to the optical film layer 40.

In an exemplary embodiment, a refractive index of a film layer in the optical film layer 40 adjacent to the sacrificial layer 50 is greater than the refractive index of the sacrificial layer 50, which may increase the ratio of the returned light.

In an exemplary embodiment, the thickness of the optical film layer 40 may be set in a range from 2.0 microns (u m) to 5.0 microns (u m). The thickness of the optical film 40 can be adjusted according to incident energy of different lights.

In an exemplary embodiment, the optical film 40 has higher stiffness than the sacrificial layer 50, that is, the stiffness of the optical film 40 is greater than a stiffness of the sacrificial layer 50, so that the optical film 40 can not only provide stable support for the substrate material layer 20, but also serve as a protective layer. When small molecular foreign matter is precipitated on the surface of the carrier substrate 10, the optical film 40 can well isolate adverse effects caused by foreign matter on the substrate material layer 20. For example, the optical film 40 can reduce the probability of defects, such as bubbling, in the substrate material layer 20 and improve an overall qualified rate of the display product.

In an exemplary embodiment, the substrate material layer 20 may include one of polyimide (PI), polyacrylate, polyphenylene sulfide, polyaryl ester, cellulose acetate propionate, polyethylene naphthalate (PEN), polyethylene terephthalate (PET), polyethersulfone resin (PES), polycarbonate (PC), polyetherimide (PEI), cycloolefin polymer (COP), silica gel resin, polyaryl compound (PAR) or glass fiber reinforced plastic (FRP), or a mixture of a plurality of polymers. The substrate material layer 20 may be of a same material as the sacrificial layer 50.

In an exemplary embodiment, the thickness of the substrate material layer 20 may be set in a range from 6.0 microns (μm) to 50 microns (μm).

In an exemplary embodiment, as shown in FIG. 2, the display substrate according to the embodiment of the present disclosure further includes a circuit structure layer 301, a conductive layer 302 and a light emitting element 60. The circuit structure layer 301 is disposed on the substrate structure layer. The circuit structure layer 301 may be disposed on a side of the substrate material layer 20 away from the sacrificial layer 50. The circuit structure layer 301 includes a drive transistor (TFT). The drive transistor may include a gate electrode, a gate insulation layer, a semiconductor layer, a source electrode, and a drain electrode. The circuit structure layer 301 is configured to drive the light emitting element 60 to emit light.

In an exemplary embodiment, the semiconductor layer of the drive transistor may include silicon, such as amorphous silicon (a-Si), polycrystalline silicon (poly-Si) or low temperature polycrystalline silicon or may include an oxide, such as indium gallium zinc oxide (IGZO), but an implementation of the present disclosure is not limited thereto.

In an exemplary embodiment, the conductive layer 302 includes a first electrode and a second electrode. One end of each of the first electrode and the second electrode is electrically connected to the circuit structure layer 301, and the other end of each of the first electrode and the second electrode is electrically connected to the light emitting element 60. The light emitting element 60 is electrically connected to the circuit structure layer 301 through the first electrode and the second electrode, thereby enabling the circuit structure layer 301 to drive the light emitting element 60 to emit light.

As shown in FIG. 2, the display substrate according to the embodiment of the present disclosure further includes an insulation layer 303 located between the circuit structure layer 301 and the conductive layer 302. The insulation layer 303 is provided with an opening 304 penetrating a thickness of the insulation layer 303 (along the Z direction). The opening 304 is configured to expose a portion of the circuit structure layer 301. The first electrode or the second electrode is electrically connected to the circuit structure layer 301 through the opening 304.

In an exemplary embodiment, the insulation layer 303 may be made of an organic material, such as polyamide, polyurethane, phenolic resin, polysiloxane and the like. If the insulation layer 303 is made of an organic material, not only better insulation property can be obtained, but also better flexibility can be obtained.

In an exemplary embodiment, as shown in FIG. 2, the light emitting element 60 may be a micro light emitting diode (Micro-LED) or a sub-millimeter light emitting diode (Mini-LED).

In an exemplary embodiment, as shown in FIG. 2, the display substrate according to the embodiment of the present disclosure further includes a protective layer 305 located on a side of the conductive layer 302 away from the circuit structure layer 301. The protective layer 305 is provided with a via 306, and the light emitting element 60 is connected to the first electrode and the second electrode through the via 306. The protective layer 305 may be made of an organic material, for example, a polymer such as acrylate, epoxy, polyurethane and the like. Or, the protective layer 305 may be made of an inorganic material, such as silicon oxynitride (SiOₓN_{y}), silicon nitride (SiN), silicon oxide (SiO), or silicon dioxide (SiO₂), etc. Metal material contained in the conductive layer 302 can be prevented from being oxidized by providing the protective layer 305.

The “patterning process” mentioned in the present disclosure includes procedures such as deposition of a film layer, coating of a photoresist, mask exposure, development, etching, and lift-off of photoresist, and is a mature preparation process in related art. The deposition may be a known process such as sputtering, vapor deposition, and chemical vapor deposition. The deposition may be a known process such as sputtering or chemical vapor deposition, the coating may be a known coating process, and the etching may be a known approach, which are not specifically limited here.

A method for manufacturing a display substrate includes following steps:

(1) Providing a carrier substrate.

Providing a carrier substrate may include operations such as cleaning and drying the carrier substrate. The carrier substrate can be made of hard material, so that the carrier substrate can provide stable support for the display substrate and has high laser transmittance, which can improve a lift-off efficiency of the display substrate and the carrier substrate.

For example, quartz glass can be used for the carrier substrate. The quartz glass is an amorphous material with a single component of SiO₂, and its microstructure is a simple network composed of SiO₂ tetrahedral structural units. Because of the large Si—O chemical bond energy and the compact microstructure of the quartz glass, the quartz glass has good optical properties and high transmittance in a continuous wavelength range from ultraviolet to infrared.

(2) Manufacturing a sacrificial layer.

Manufacturing a sacrificial layer includes: forming the sacrificial layer by a coating process or the like. The sacrificial layer can be manufactured by a single coating operation or by multiple coating operations.

The coating process includes scraping coating, roll coating, ultrasonic spraying and slit coating.

Or, the sacrificial layer is formed by ink jet printing, screen printing, flash evaporation or Plasma Enhanced Chemical Vapor Deposition (PECVD) or the like.

(3) Manufacturing an optical film layer.

Manufacturing an optical film layer includes: forming the optical film by PECVD, atomic layer deposition (PEALD), magnetron Sputter (Sputter), or the like.

(4) Manufacturing a substrate material layer.

A process of manufacturing a substrate material layer includes: forming the substrate material layer by a coating process or the like.

Or, the substrate material layer is formed by ink jet printing, screen printing, flash evaporation, PECVD or the like.

The process of manufacturing the substrate material layer can be set to be the same as the process of manufacturing the sacrificial layer, so as to reduce switching between different processes and reduce manufacturing investment.

Or, a same process is selected for the sacrificial layer, the optical film layer and the substrate material layer, so as to reduce the switching between different processes and reduce the manufacturing investment.

(5) Manufacturing a circuit structure layer.

Manufacturing a circuit structure layer includes: forming the circuit structure layer by magnetron sputtering or the like.

(6) Manufacturing an insulation layer.

Manufacturing an insulation layer includes: forming the insulation layer by PECVD, atomic layer deposition, magnetron sputtering or the like. An opening is provided in the insulation layer, and the opening exposes the circuit structure layer.

(7) Manufacturing a conductive layer.

Manufacturing a conductive layer includes: forming the conductive layer by magnetron sputtering or the like. The conductive layer includes a first electrode and a second electrode, the first electrode and the second electrode are electrically connected with the circuit structure layer through an opening.

(8) Manufacturing a protective layer.

Manufacturing a protective layer includes: forming the protective layer by PECVD, atomic layer deposition, magnetron sputtering or the like. A via is provided in the protective layer.

(9) Installing a light emitting element.

Installing a light emitting element includes: connecting the light emitting element electrically with the first electrode and the second electrode respectively through a via by a die bonding process. The die bonding process is also called Die Bond or Die Attach. The die bonding process is a process of bonding the wafer to a designated area of the bracket through colloid, which is generally conductive adhesive or insulating adhesive for LED, to form a thermal path or an electrical path, which provides conditions for subsequent wire connection.

Or, the light emitting element is electrically connected with the first electrode and the second electrode respectively through a via by a welding process. For example, the welding metal may be printed at a connection pattern position by printing (for example, as shown in FIG. 2, the welding metal is printed at the via 306), and then the light emitting element is welded at the corresponding connection pattern position.

(10) Lifting off the display substrate.

Lifting off the display substrate includes: irradiating the sacrificial layer from a side of the carrier substrate away from the sacrificial layer by laser, that is, the laser passes through the carrier substrate and then irradiates the sacrificial layer, so that the sacrificial layer is lifted off from the carrier substrate to obtain the display substrate.

An embodiment of the present disclosure further provides a method for manufacturing a display substrate. The method includes:
forming a sacrificial layer on a carrier substrate;
forming an optical film layer on the sacrificial layer;
forming a substrate material layer on the optical film layer;
irradiating the sacrificial layer from a side of the carrier substrate away from the sacrificial layer by using lift-off light to lift the sacrificial layer off from the carrier substrate, wherein a reflectivity of the optical film layer is greater than a transmittance of the optical film layer.

Through the introduction of the technical proposal and the preparation process, it can be seen that the display substrate provided by the embodiments of the present disclosure can be a laser lift-off process to lift off the sacrificial layer from the carrier substrate. In this display substrate, the optical film layer is configured to have a reflectivity greater than a transmittance thereof, so that the proportion of lift-off light penetrating through the substrate material layer can be reduced, the damages caused by lift-off light to the circuit structure layer and the like in the display substrate can be avoided, and the qualified rate of the product can be improved, and the overall manufacturing cost of the display product can be reduced. In addition, the method for manufacturing the display substrate according to an embodiment of the disclosure can be implemented by utilizing the existing mature manufacturing equipment, which has the advantages of little modification on the existing process, simple manufacturing process, low production cost and high production precision, and has a good application prospect.

A display device is further provided in an embodiment of the present disclosure. The display device includes the display substrate described in any of the above embodiments. The display device may be any product or component with a display function, such as a mobile phone, a tablet computer, a television, a laptop computer, a digital photo frame, or a navigator.

Although the embodiments disclosed in the present disclosure are described as above, the described contents are only embodiments which are adopted in order to facilitate understanding of the present invention, and are not intended to limit the present disclosure. Any skilled person in the art to which the present invention pertains can make any modifications and alterations to forms and details of implementation without departing from the spirit and scope of the present invention. However, the patent protection scope of the present invention should be subject to the scope defined by the appended claims.

1. A display substrate, comprising a substrate structure layer; the substrate structure layer comprises a substrate material layer, a sacrificial layer and an optical film layer between the substrate material layer and the sacrificial layer which are stacked; a reflectivity of the optical film layer is greater than a transmittance of the optical film layer.

2. The display substrate according to claim 1, wherein the optical film layer comprises at least one first dielectric layer and at least one second dielectric layer, and a refractive index of the at least one first dielectric layer is less than a refractive index of the at least one second dielectric layer; the at least one first dielectric layer and the at least one second dielectric layer are arranged in an overlapped manner along a direction away from the sacrificial layer.

3. The display substrate according to claim 2, wherein a film layer in the optical film layer adjacent to the substrate material layer is a first dielectric layer, and a film layer in the optical film layer adjacent to the sacrificial layer is a first dielectric layer.

4. The display substrate according to claim 2, wherein a film layer in the optical film layer adjacent to the substrate material layer is a second dielectric layer, and a film layer in the optical film layer adjacent to the sacrificial layer is a second dielectric layer.

5. The display substrate according to claim 2, wherein the at least one first dielectric layer and the at least one second dielectric layer are both made of organic materials.

6. The display substrate according to claim 2, wherein a refractive index of a film layer in the optical film layer adjacent to the substrate material layer is greater than a refractive index of the substrate material layer.

7. The display substrate according to claim 2, wherein, a refractive index of a film layer in the optical film layer adjacent to the sacrificial layer is greater than a refractive index of the sacrificial layer.

8. The display substrate according to claim 1, wherein a thickness of the sacrificial layer is 2.0 microns to 5.0 microns.

9. The display substrate according to claim 1, wherein a material of the sacrificial layer is a photosensitive organic material or a photosensitive photoresist material.

10. The display substrate according to claim 1, wherein a material of the sacrificial layer is the same as a material of the substrate material layer.

11. The display substrate of claim 1, further comprising a circuit structure layer disposed on a side of the substrate material layer away from the sacrificial layer.

12. The display substrate according to claim 11, further comprising a light emitting element disposed on a side of the circuit structure layer away from the substrate structure layer, and the light emitting element is connected to the circuit structure layer.

13. The display substrate according to claim 12, wherein the light emitting element is a micro light emitting diode or a sub-millimeter light emitting diode.

14. A display device, comprising the display substrate according to claim 1.

15. A method for manufacturing a display substrate, comprising:
forming a sacrificial layer on a carrier substrate;
forming an optical film layer on the sacrificial layer;
forming a substrate material layer on the optical film layer; and
irradiating the sacrificial layer from a side of the carrier substrate away from the sacrificial layer by using lift-off light to lift the sacrificial layer off from the carrier substrate, wherein a reflectivity of the optical film layer is greater than a transmittance of the optical film layer.

16. The display substrate according to claim 3, wherein the at least one first dielectric layer and the at least one second dielectric layer are both made of organic materials.

17. The display substrate according to claim 4, wherein the at least one first dielectric layer and the at least one second dielectric layer are both made of organic materials.

18. The display substrate according to claim 3, wherein a refractive index of a film layer in the optical film layer adjacent to the substrate material layer is greater than a refractive index of the substrate material layer.

19. The display substrate according to claim 4, wherein a refractive index of a film layer in the optical film layer adjacent to the substrate material layer is greater than a refractive index of the substrate material layer.

20. The display substrate according to claim 3, wherein, a refractive index of a film layer in the optical film layer adjacent to the sacrificial layer is greater than a refractive index of the sacrificial layer.
